(19) United States
(12) Patent Application Publication
(10) Pub. No.: US 2026/0205116 A1
(43) Pub. Date: Jul. 16, 2026

(54) ELECTRONIC CIRCUIT, ELECTRONIC DEVICE, AND WIRELESS COMMUNICATION DEVICE

(71) Applicant: SEIKO GROUP CORPORATION, Tokyo (JP)

(72) Inventors: Ryosuke ISOGAI, Matsudo-shi (JP); Yoshifumi YOSHIDA, Matsudo-shi (JP)

(21) Appl. No.: 19/137,969

(22) PCT Filed: Nov. 9, 2023
(86) PCT No.: PCT/JP2023/040460

§ 371 Date: Jun. 11, 2025

(30) Foreign Application Priority Data
Dec. 21, 2022 (JP) 2022-203946

(51) Int. Cl. H03K 17/945; H03K 17/689; H03K 17/78

(52) U.S. Cl. CPC H03K 17/945; H03K 17/689; H03K 17/78

(57) ABSTRACT

An electronic circuit includes: a first switch including a first terminal connected to a power supply, a second terminal, and a control input terminal and electrically connecting the first terminal and the second terminal when a negative voltage greater than a predetermined threshold voltage with respect to a source voltage applied to the first terminal is applied to the control input terminal; and a photovoltaic element connected in a forward direction between the power supply and the control input terminal of the first switch and applying a negative voltage greater than the threshold voltage of the first switch with respect to the source voltage to the control input terminal of the first switch using photovoltaic power which is generated by irradiation with light.

### RELATED APPLICATIONS

This application is a 371 application of PCT/JP2023/040460 having an international filing date of Nov. 9, 2023, which claims priority to Japanese Patent Application No. 2022-203946, filed Dec. 21, 2022, the entire content of each of which is incorporated herein by reference.

### TECHNICAL FIELD

The present invention relates to an electronic circuit, an electronic device, and a wireless communication device.

### BACKGROUND ART

In the related art, in order to relieve a user from having to insert a battery in an electronic device for use as a power supply, the battery is directly mounted on a substrate in advance, or the battery is inserted in advance. A technique of preventing the battery from being consumed by discharging (waiting electric power) before a user uses the electronic device is described, for example, in Patent Document 1. In the technique described in Patent Document 1, power supply on/off control is performed using a light latch circuit using photovoltaic power which is generated from a light emitting diode (LED) when it is irradiated with light.

The optical latch circuit described in Patent Document 1 includes a voltage detector comparing a first generated voltage input from a first input terminal with a preset first threshold voltage and outputting a set signal from a determination output terminal when the first generated voltage is greater than the first threshold voltage, a first photovoltaic element forwardly connected between the first input terminal and a ground point and outputting the first generated voltage based on photovoltaic power to the first input terminal when it is irradiated with light, and a feedback resistor interposed between the first input terminal and the determination output terminal.

### CITATION LIST

### Patent Document

Patent Document 1: Japanese Unexamined Patent Application, First Publication No. 2020-161920

### SUMMARY

### Technical Problem

However, in the optical latch circuit described in Patent Document 1, the first generated voltage output from the first photovoltaic element based on photovoltaic power when it is irradiated with light is input to the first input terminal of the voltage detector and is compared with the first threshold voltage by the voltage detector. However, since the first generated voltage is a plus voltage, an input circuit to the first input terminal of the voltage detector has to be formed in positive logic, and thus it is difficult to diversify the input circuit. Accordingly, there is a problem in that it is difficult to practically use power supply on/off control using the optical latch circuit.

The present invention was made in consideration of the aforementioned circumstances, and an objective thereof is to achieve improvement of power supply on/off control using photovoltaic power which is generated from a photovoltaic element such as a light emitting diode in response to irradiation with light.

### Solution to Problem

According to an aspect of the present invention, there is provided an electronic circuit including: a first switch including a first terminal connected to a power supply, a second terminal, and a control input terminal and electrically connecting the first terminal and the second terminal when a negative voltage greater than a predetermined threshold voltage with respect to a source voltage applied to the first terminal is applied to the control input terminal; and a photovoltaic element connected in a forward direction between the power supply and the control input terminal of the first switch and applying a negative voltage greater than the threshold voltage of the first switch with respect to the source voltage to the control input terminal of the first switch using photovoltaic power which is generated by irradiation with light.

In the electronic circuit according to the aspect of the present invention, the first switch is a P-channel MOSFET, the first terminal of the first switch is a source of the P-channel MOSFET, the second terminal of the first switch is a drain of the P-channel MOSFET, and the control input terminal of the first switch is a gate of the P-channel MOSFET.

The electronic circuit according to the aspect of the present invention further includes a pull-up resistor that is connected in parallel to the photovoltaic element between the power supply and the control input terminal of the first switch.

The electronic circuit according to the aspect of the present invention further includes a second switch including a first terminal connected to the control input terminal of the first switch, a second terminal supplied with a negative voltage greater than the threshold voltage of the first switch with respect to the source voltage, and a control input terminal supplied with an external control signal input from the outside of the electronic circuit and electrically connecting the first terminal and the second terminal in response to the external control signal.

In the electronic circuit according to the aspect of the present invention, the second switch is an N-channel MOSFET, the first terminal of the second switch is a drain of the N-channel MOSFET, the second terminal of the second switch is a source of the N-channel MOSFET, and the control input terminal of the second switch is a gate of the N-channel MOSFET.

In the electronic circuit according to the aspect of the present invention, the second terminal of the second switch is grounded or supplied with a negative source voltage of the power supply.

The electronic circuit according to the aspect of the present invention further includes a third switch including a first terminal connected to the power supply, a second terminal, and a control input terminal and electrically connecting the first terminal and the second terminal when a negative voltage greater than a predetermined threshold voltage with respect to the source voltage applied to the first terminal is applied to the control input terminal, and the photovoltaic element is further connected in a forward direction between the power supply and the control input terminal of the third switch.

The electronic circuit according to the aspect of the present invention further includes a voltage division resistor connected in series to the pull-up resistor between a cathode of the photovoltaic element and the control input terminal of the first switch, and a relationship in resistance value between the pull-up resistor and the voltage division resistor is set such that a negative voltage greater than the threshold voltage of the third switch with respect to the source voltage is not applied to the control input terminal of the third switch when the first terminal and the second terminal of the second switch are electrically connected.

In the electronic circuit according to the aspect of the present invention, the third switch is a P-channel MOSFET, the first terminal of the third switch is a source of the P-channel MOSFET, the second terminal of the third switch is a drain of the P-channel MOSFET, and the control input terminal of the third switch is a gate of the P-channel MOSFET.

In the electronic circuit according to the aspect of the present invention, the photovoltaic element is a red light emitting diode or an infrared light emitting diode.

In the electronic circuit according to the aspect of the present invention, a predetermined control process is performed by irradiating the photovoltaic element with specific pulsed light.

According to another aspect of the present invention, there is provided an electronic device including: the aforementioned electronic circuit; the power supply; and a load circuit supplied with electric power of the power supply from the second terminal of the first switch.

According to another aspect of the present invention, there is provided an electronic device including: the aforementioned electronic circuit; the power supply; and a control circuit supplied with electric power of the power supply from the second terminal of the first switch, wherein the control circuit outputs an external control signal supplied to the control input terminal of the second switch.

In the electronic device according to this aspect of the present invention, the control circuit outputs the external control signal when a predetermined time elapses after the control circuit has started.

According to another aspect of the present invention, there is provided a wireless communication device including: a first switch including a first terminal connected to a power supply, a second terminal, and a control input terminal and electrically connecting the first terminal and the second terminal when a negative voltage greater than a predetermined threshold voltage with respect to a source voltage applied to the first terminal is applied to the control input terminal; and a photovoltaic element connected in a forward direction between the power supply and the control input terminal of the first switch and applying a negative voltage greater than the threshold voltage of the first switch with respect to the source voltage to the control input terminal of the first switch using photovoltaic power which is generated by irradiation with light, wherein radio waves are emitted in response to irradiation of the photovoltaic element with light.

According to the present invention, it is possible to achieve improvement of power supply on/off control using photovoltaic power which is generated from a photovoltaic element such as a light emitting diode in response to irradiation with light.

### DRAWINGS

FIG. 1 is a block diagram illustrating a configuration example of an electronic device according to a first embodiment.

FIG. 2 is a diagram illustrating a specific configuration example of the electronic device according to the first embodiment.

FIG. 3 is a flowchart illustrating an operation example of an electronic circuit according to the first embodiment.

FIG. 4 is a diagram illustrating a specific configuration example of an electronic device according to a second embodiment.

FIG. 5 is a diagram illustrating a specific configuration example of an electronic device 1 according to a third embodiment.

FIG. 6 is a flowchart illustrating an operation example of an electronic circuit according to the third embodiment.

FIG. 7 is a diagram illustrating a specific configuration example of an electronic device according to a fourth embodiment.

FIG. 8 is a diagram illustrating another specific configuration example of the electronic device according to the fourth embodiment.

### DESCRIPTION OF EMBODIMENTS

Hereinafter, embodiments of the present invention will be described with reference to the accompanying drawings.

### First Embodiment

FIG. 1 is a block diagram illustrating a configuration example of an electronic device 1 according to a first embodiment. In FIG. 1, the electronic device 1 includes an electronic circuit 10, a power supply BT, and a load circuit 30. The electronic circuit 10 is a circuit that is used to perform power supply on-off control using photovoltaic power which is generated from a photovoltaic element such as a light emitting diode in response to irradiation with light. The electronic circuit 10 switches between on (supply of electric power) and off (non-supply of electric power) when electric power from the power supply BT is supplied to the load circuit 30. The load circuit 30 is supplied with electric power from the power supply BT via the electronic circuit 10.

The power supply BT is, for example, a battery. In order to relieve a user's labor for inserting the battery in the electronic device 1 in which a battery is used as the power supply BT, the battery is directly mounted on a substrate in advance, or the battery is inserted in advance.

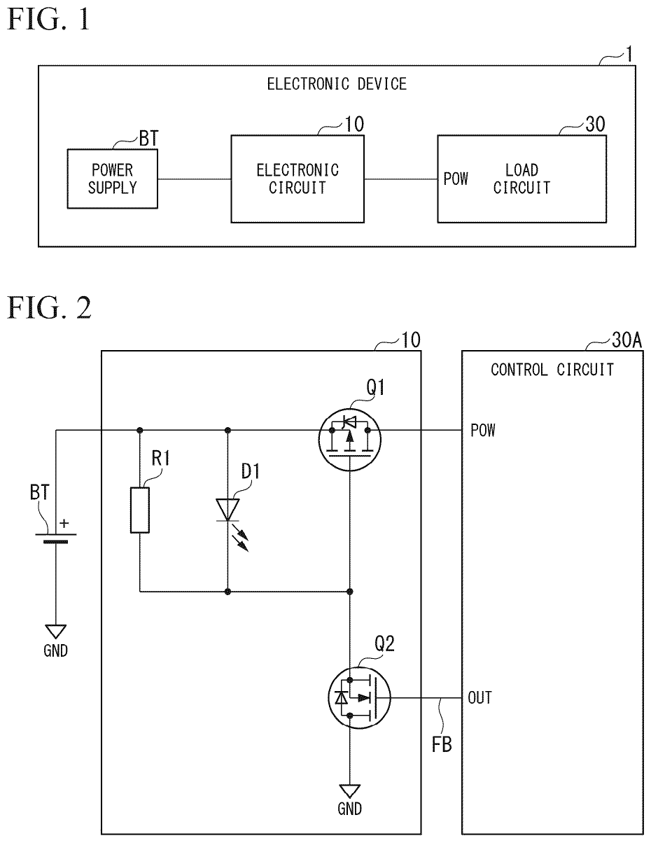

FIG. 2 is a diagram illustrating a specific configuration example of the electronic device 1 according to the first embodiment. FIG. 2 illustrates an example of a specific circuit configuration of the electronic circuit 10.

In FIG. 2, the electronic circuit 10 includes a P-channel metal oxide semiconductor field effect transistor (MOSFET) Q1 (first switch), an N-channel MOSFET Q2 (a second switch), a light emitting diode D1, and a pull-up resistor R1.

The light emitting diode D1 is an example of a photovoltaic element. For example, a photodiode or a solar cell may be used as the photovoltaic element in addition to the light emitting diode.

A source (a first terminal) of the P-channel MOSFET Q1 is connected to a plus terminal of the power supply BT, an anode of the light emitting diode D1, and one terminal (a first terminal) of the pull-up resistor R1. A minus terminal of the power supply BT is connected to a ground terminal GND (0 volts (V)) of the electronic device 1.

A drain (a second terminal) of the P-channel MOSFET Q1 is connected to a power supply terminal POW of a control circuit 30A. The control circuit 30A is an example of the load circuit 30. The control circuit 30A operates with electric power supplied to the power supply terminal POW. The control circuit 30A starts when electric power is supplied to the power supply terminal POW.

The control circuit 30A is, for example, a microcomputer. The microcomputer which is the control circuit 30A realizes the function of the control circuit 30A by executing a predetermined program.

A gate (a control input terminal) of the P-channel MOSFET Q1 is connected to a cathode of the light emitting diode D1, one terminal (a second terminal) of the pull-up resistor R1, and a source (a first terminal) of the N-channel MOSFET Q2.

The light emitting diode D1 is connected in a forward direction between the plus terminal of the power supply BT and the gate of the P-channel MOSFET Q1. That is, the anode of the light emitting diode D1 is connected to the plus terminal of the power supply BT, and the cathode of the light emitting diode D1 is connected to the gate of the P-channel MOSFET Q1.

The pull-up resistor R1 is connected in parallel to the light emitting diode D1 between the plus terminal of the power supply BT and the gate of the P-channel MOSFET Q1. That is, one terminal (a first terminal) of the pull-up resistor R1 is connected to the plus terminal of the power supply BT and the anode of the light emitting diode D1, and the other terminal (a second terminal) of the pull-up resistor R1 is connected to the gate of the P-channel MOSFET Q1 and the cathode of the light emitting diode D1.

A drain (a first terminal) of the N-channel MOSFET Q2 is connected to the gate of the P-channel MOSFET Q1, the cathode of the light emitting diode D1, and one terminal (the second terminal) of the pull-up resistor R1.

A source (a second terminal) of the N-channel MOSFET Q2 is connected to the ground terminal GND of the electronic device 1. Accordingly, the source of the N-channel MOSFET Q2 is supplied with the same voltage as a minus source voltage (a negative source voltage (0 V)) of the power supply BT.

A gate (a control input terminal) of the N-channel MOSFET Q2 is connected to an output terminal OUT of the control circuit 30A. The control circuit 30A outputs an external control signal FB from the output terminal OUT. Accordingly, the external control signal FB output from the output terminal OUT of the control circuit 30A is input to the gate of the N-channel MOSFET Q2. Accordingly, the external control signal FB is a signal for controlling ON/OFF of electrical connection between the source and the drain of the N-channel MOSFET Q2.

When a minus voltage (a negative voltage) greater than a predetermined threshold voltage VTH1 with respect to a plus source voltage of the power supply BT (hereinafter referred to as a source voltage) supplied to the source thereof is applied to the gate thereof, the P-channel MOSFET Q1 electrically connects the source and the drain (an electrically connected state). On the other hand, when the negative voltage applied to the gate with respect to the source voltage applied to the source is not greater than the threshold voltage VTH1, the P-channel MOSFET Q1 electrically disconnects the source and the drain (an electrically disconnected state).

When the source and the drain of the P-channel MOSFET Q1 are electrically connected, electric power is supplied from the power supply BT to the control circuit 30A. On the other hand, when the source and the drain of the P-channel MOSFET Q1 are electrically disconnected, electric power is not supplied form the power supply BT to the control circuit 30A.

When a plus voltage (a positive voltage) greater than a predetermined threshold voltage VTH2 with respect to a voltage applied to the source is applied to the gate, the N-channel MOSFET Q2 electrically connects the source and the drain (the electrically connected state). On the other hand, when a positive voltage applied to the gate with respect to the voltage applied to the source is not greater than the threshold voltage VTH2, the N-channel MOSFET Q2 electrically disconnects the source and the drain (the electrically disconnected state).

When the source and the drain of the N-channel MOSFET Q2 are electrically connected, a negative source voltage is supplied to the gate of the P-channel MOSFET Q1. The negative source voltage is a negative voltage greater than the threshold voltage VTH1 with respect to the source voltage. Accordingly, when the source and the drain of the N-channel MOSFET Q2 are electrically connected, the source and the drain of the P-channel MOSFET Q1 are electrically connected.

Since ON/OFF of electrical connection between the source and the drain of the N-channel MOSFET Q2 is controlled by the external control signal FB, the source and the drain of the P-channel MOSFET Q1 can be electrically connected by the external control signal FB. Specifically, when the control circuit 30A outputs the external control signal FB as a level of the source voltage (a high level (H level)), the source and the drain of the N-channel MOSFET Q2 can be electrically connected, and the source and the drain of the P-channel MOSFET QI can be electrically connected. On the other hand, when the control circuit 30A outputs the external control signal FB at a level of the negative source voltage (a low level (L level)) of the power supply BT, the source and the drain of the N-channel MOSFET Q2 can be electrically disconnected.

The light emitting diode D1 supplies a negative voltage greater than the threshold voltage VTH1 with respect to the source voltage to the gate of the P-channel MOSFET Q1 using photovoltaic power generated by irradiation with light.

When the source and the drain of the N-channel MOSFET Q2 are electrically disconnected and the light emitting diode D1 is not irradiated with light, photovoltaic power of the light emitting diode D1 is not generated, and the source voltage is applied to the gate of the P-channel MOSFET Q1 by the pull-up resistor R1 connected in parallel to the light emitting diode D1. Accordingly, when the source and the drain of the N-channel MOSFET Q2 are electrically disconnected and the light emitting diode D1 is not irradiated with light, the condition of the threshold voltage VTH1 of the P-channel MOSFET Q1 is not satisfied, the source and the drain of the P-channel MOSFET Q1 are electrically disconnected, and thus electric power is not supplied from the power supply BT to the control circuit 30A. At this time, a current flowing from the power supply BT is only a leak current when the P-channel MOSFET Q1 and the N-channel MOSFET Q2 are turned off (the electrically disconnected state), and thus it is possible to realize a very small waiting current.

When the light emitting diode D1 is irradiated with light, a higher voltage is generated in the anode than that in the cathode of the light emitting diode D1 (so-called photovoltaic power is generated). Accordingly, when the source and the drain of the N-channel MOSFET Q2 are electrically disconnected and the light emitting diode D1 is irradiated with light, a voltage lower by the photovoltaic power than the source voltage applied to the source is applied to the gate of the P-channel MOSFET Q1 using the photovoltaic power of the light emitting diode D1.

At this time, since a potential difference is caused between both terminals of the pull-up resistor R1, a current flows in the pull-up resistor R1, and the current flowing in the pull-up resistor R1 can be sufficiently decreased in comparison with a current generated in the light emitting diode D1 when a resistance value of the pull-up resistor R1 is set to a sufficiently large value, and thus it is possible to ignore an influence of the current flowing in the pull-up resistor R1. Since the current generated in the light emitting diode D1 ranges generally from several tens of microampere (μA) to several hundreds of μA, it is preferable that the resistance value of the pull-up resistor R1 be equal to or greater than 100 kilo-ohm (kΩ).

When the source and the drain of the N-channel MOSFET Q2 are electrically disconnected and a negative voltage greater than the threshold voltage VTH1 with respect to the source voltage applied to the source is applied to the gate of the P-channel MOSFET Q1 using the photovoltaic power of the light emitting diode D1 generated by irradiation with light, the source and the drain of the P-channel MOSFET Q1 are electrically connected, and electric power is supplied from the power supply BT to the control circuit 30A. At this time, when irradiation of the light emitting diode D1 with light stops, the photovoltaic power of the light emitting diode D1 disappears and the condition of the threshold voltage VTH1 of the P-channel MOSFET Q1 is not satisfied. Accordingly, the source and the drain of the P-channel MOSFET Q1 are electrically disconnected, and electric power is not supplied from the power supply BT to the control circuit 30A.

In the electronic circuit 10 illustrated in FIG. 2, the condition of the threshold voltage VTH1 of the P-channel MOSFET Q1 is that the voltage applied to the gate is a negative voltage greater than the threshold voltage VTH1 with respect to the source voltage applied to the source. Accordingly, even when the source voltage is decreased for any reason, the voltage applied to the gate by the photovoltaic power of the light emitting diode D1 is “(source voltage)—(voltage corresponding to photovoltaic power), and decreases by the amount of the decrease in the source voltage. However, since the source voltage which is applied to the source and which serves as a reference voltage of the condition of the threshold voltage VTH1 decreases in the same way, the decrease in source voltage does not affect the condition of the threshold voltage VTH1. This is true when the source voltage increases for any reason. Accordingly, when the source voltage fluctuates in the electronic circuit 10 illustrated in FIG. 2, the P-channel MOSFET Q1 can perform a stable switching operation without being affected by the fluctuation of the source voltage. This is an advantage using a MOSFET in comparison with a general voltage detection circuit using a fixed threshold value, and it is preferable to realize a voltage detecting function using the MOSFET for a simple configuration.

With the electronic circuit 10 illustrated in FIG. 2, when the external control signal FB is at the L level, the source and the drain of the N-channel MOSFET Q2 are electrically disconnected, and thus electrical connection between the source and the drain of the P-channel MOSFET Q1 can be switched between ON and OFF according to whether the light emitting diode D1 is irradiated with light. Accordingly, when the external control signal FB is at the L level, it is possible to switch supply of electric power from the power supply BT to the control circuit 30A between ON and OFF according to whether the light emitting diode D1 is irradiated with light. The control circuit 30A is configured such that the external control signal FB is at the L level when the control circuit 30A is in a non-starting state.

On the other hand, when the external control signal FB is at the H level, the source and the drain of the N-channel MOSFET Q2 are electrically connected, and thus the source and the drain of the P-channel MOSFET Q1 can be fixed to the electrically connected state regardless of whether the light emitting diode D1 is irradiated with light.

Accordingly, the source and the drain of the P-channel MOSFET Q1 are electrically connected to start supply of electric power from the power supply BT to the control circuit 30A by irradiating the light emitting diode D1 with light when the control circuit 30A is in the non-starting state, and the electrically connected state between the source and the drain of the P-channel MOSFET Q1 is fixed to continue to supply electric power from the power supply BT to the control circuit 30A by changing the external control signal FB from the L level to the H level after the control circuit 30A has started.

The electrically connected state between the source and the drain of the P-channel MOSFET Q1 can be switched to the electrically disconnected state to stop supply of electric power from the power supply BT to the control circuit 30A by the control circuit 30A changing the external control signal FB from the H level to the L level in a state in which the light emitting diode D1 is not irradiated with light.

When a predetermined waiting time elapses after the control circuit 30A has started, the control circuit 30A may change the external control signal FB from the L level to the H level. This causes an effect of curbing an influence of noise or unexpected irradiation of the light emitting diode D1 with light on an erroneous operation of the power supply on/off control. This point will be described below. Even when the source and the drain of the P-channel MOSFET Q1 are electrically connected by noise or unexpected irradiation of the light emitting diode D1 with light, supply of electric power from the power supply BT to the control circuit 30A is started, and the control circuit 30A starts, the external control signal FB is not immediately changed from the L level to the H level due to the waiting time. Here, it is thought that the electrically connected state between the source and the drain of the P-channel MOSFET Q1 (that is, supply of electric power from the power supply BT to the control circuit 30A) is not maintained with noise or unexpected irradiation of the light emitting diode D1 with light. Accordingly, even when the control circuit 30A is started with noise or unexpected irradiation of the light emitting diode D1 with light, the control circuit 30A does not continue to operate until a predetermined waiting time elapses after the control circuit 30A has started, and thus the control circuit 30A does not change the external control signal FB from the L level to the H level. As a result, even when supply of electric power from the power supply BT to the control circuit 30A is erroneously started with noise or unexpected irradiation of the light emitting diode D1 with light, supply of electric power from the power supply BT to the control circuit 30A is not maintained, and thus it is possible to curb consumption of the power supply BT.

The control circuit 30A may control the external control signal FB on the basis of an internal state thereof. For example, when the control circuit 30A cannot perform a regular operation after having started, the control circuit 30A maintains the external control signal FB at the L level. Accordingly, when irradiation of the light emitting diode D1 with light stops, supply of electric power from the power supply BT to the control circuit 30A stops, and thus it is possible to prevent the control circuit 30A from continuing to operate in a state in which the control circuit 30A cannot perform a regular operation.

As the light emitting diode D1, a red light emitting diode (a red LED) or an infrared light emitting diode (an infrared LED) may be used. When a red LED or an infrared LED is used as the light emitting diode D1, it is preferable that a wavelength of light with which the light emitting diode D1 is irradiated range from 840 nanometer (nm) to 950 nm. This is because an infrared LED on the light emission side generating light with a large output is easily available and thus easily generates sufficiently strong infrared light.

By generating sufficiently strong infrared light from the infrared LED with a large output and irradiating the light emitting diode D1 (the red LED or the infrared LED) with the infrared light, it is possible to reliably generate photovoltaic power of the light emitting diode D1 even when a distance between the infrared LED on the light emission side and the light emitting diode D1 is some distance apart. Since such strong infrared light is invisible light, a user cannot feel discomfort. Since photovoltaic power of the light emitting diode D1 can be sufficiently generated using strong infrared light, it is possible to prevent an erroneous operation due to noise.

When the power supply BT is, for example, a silver oxide battery (with a nominal voltage of 1.55 V) or a zinc air battery (with a nominal voltage of 1.4 V), the threshold voltage VTH1 of the P-channel MOSFET Q1 and the threshold voltage VTH2 of the N-channel MOSFET Q2 preferably range from 0.5 V to about 1.3 V.

In a specific example of the electronic circuit 10 illustrated in FIG. 2, the power supply BT is a silver oxide battery (with a source voltage of 1.55 V), a resistance value of the pull-up resistor R1 is 1 mega ohm (MΩ), the light emitting diode D1 is a red LED (a VF of 1.85 V), the threshold voltage VTH1 of the P-channel MOSFET Q1 is 0.9 V (max value), and the threshold voltage VTH2 of the N-channel MOSFET Q2 is 0.9 V (max value).

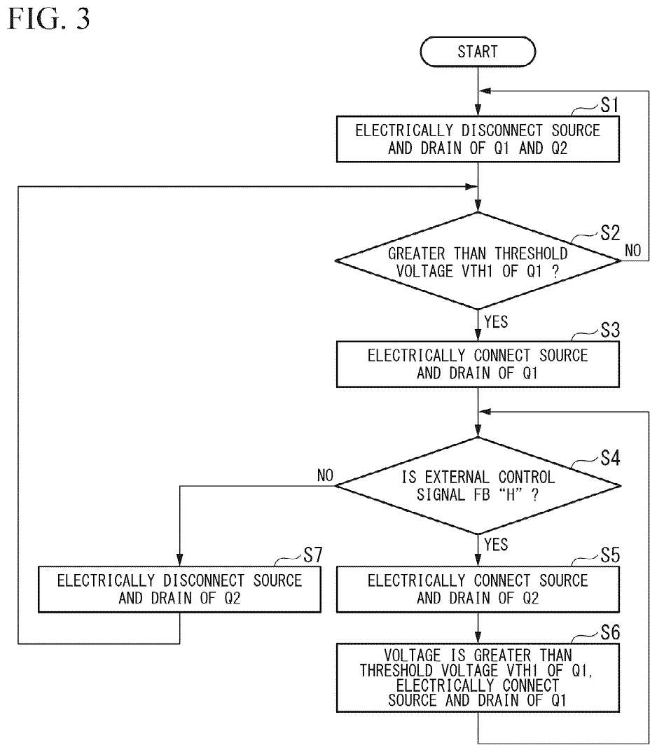

Operations of the electronic circuit 10 illustrated in FIG. 2 will be described below with reference to FIG. 3. FIG. 3 is a flowchart illustrating an operation example of the electronic circuit 10 according to the first embodiment.

In the following description, becoming in the state in which the source and the drain of the P-channel MOSFET Q1 are electrically connected may be referred to as turning-on of the P-channel MOSFET Q1, being in the state in which the source and the drain of the P-channel MOSFET Q1 are in the electrically connected state may be referred to as being-on of the P-channel MOSFET Q1, becoming in the state in which the source and the drain of the P-channel MOSFET Q1 are electrically disconnected may be referred to as turning-off of the P-channel MOSFET Q1, and being in the state in which the source and the drain of the P-channel MOSFET Q1 are in the electrically disconnected state may be referred to as being-off of the P-channel MOSFET Q1. The same naming may be similarly applied to the N-channel MOSFET Q2.

The voltage applied to the source of the P-channel MOSFET Q1 may be referred to as a source voltage, or the voltage applied to the gate of the P-channel MOSFET Q1 may be referred to as a gate voltage. The same naming may be similarly applied to the N-channel MOSFET Q2.

In an initial state, the P-channel MOSFET Q1 in the electronic circuit 10 is turned off, and the N-channel MOSFET Q2 is turned off because the external control signal FB is at the L level. Accordingly, in the initial state, electric power is not supplied from the power supply BT to the control circuit 30A.

(Step S1) In the initial state, the P-channel MOSFET Q1 and the N-channel MOSFET Q2 are turned off.

(Step S2) When the gate voltage of the P-channel MOSFET Q1 is a negative voltage greater than the threshold voltage VTH1 with respect to the source voltage (when the condition of the threshold voltage VTH1 is satisfied and the determination result of Step S2 is “YES”) by irradiation of the light emitting diode D1 with light, the process flow proceeds to Step S3. On the other hand, when the condition of the threshold voltage VTH1 is not satisfied (the determination result of Step S2 is “NO”), the process flow returns to Step S1.

(Step S3) Since the condition of the threshold voltage VTH1 is satisfied, the P-channel MOSFET Q1 is turned on. Accordingly, supply of electric power from the power supply BT to the control circuit 30A is started. The control circuit 30A starts with supply of electric power from the power supply BT.

(Step S4) When the control circuit 30A outputs the external control signal FB at the H level after having started (Step S4: YES), the process flow proceeds to Step S5. On the other hand, when the external control signal FB output from the control circuit 30A is at the L level (Step S4: NO), the process flow proceeds to Step S7.

(Step S5) Since the external control signal FB is at the H level, the N-channel MOSFET Q2 is turned on.

(Step S6) When the N-channel MOSFET Q2 is turned on, the condition of the threshold voltage VTH1 is satisfied, and thus the P-channel MOSFET Q1 continues to be turned on. When the external control signal FB is at the H level, the N-channel MOSFET Q2 is turned on, and thus the P-channel MOSFET Q1 is turned on regardless of whether the light emitting diode D1 is irradiated with light. Accordingly, when the external control signal FB is at the H level, electric power is supplied from the power supply BT to the control circuit 30A regardless of whether the light emitting diode D1 is irradiated with light.

(Step S7) Since the external control signal FB is at the L level, the N-channel MOSFET Q2 is turned off. For example, when the control circuit 30A changes the external control signal FB to the H level after having started and then a predetermined power supply stopping condition is satisfied, the control circuit 30A switches the external control signal FB from the H level to the L level. Accordingly, the N-channel MOSFET Q2 is switched from ON to OFF, and the P-channel MOSFET Q1 is switched from ON to OFF when the light emitting diode D1 is not irradiated with light at that time and thus supply of electric power from the power supply BT to the control circuit 30A stops.

After Step S7, the process flow returns to Step S2.

In the electronic circuit 10 according to the first embodiment, since an input circuit to the gate of the P-channel MOSFET Q1 which is a circuit for switching whether electric power is to be supplied from the power supply BT to the control circuit 30A can be formed in negative logic, it is possible to easily achieve diversification of the input circuit (for example, logical sum control using a plurality of open collector signals). Accordingly, it is possible to achieve improvement of power supply on/off control using photovoltaic power which is generated from a photovoltaic element such as a light emitting diode in response to irradiation with light.

### Second Embodiment

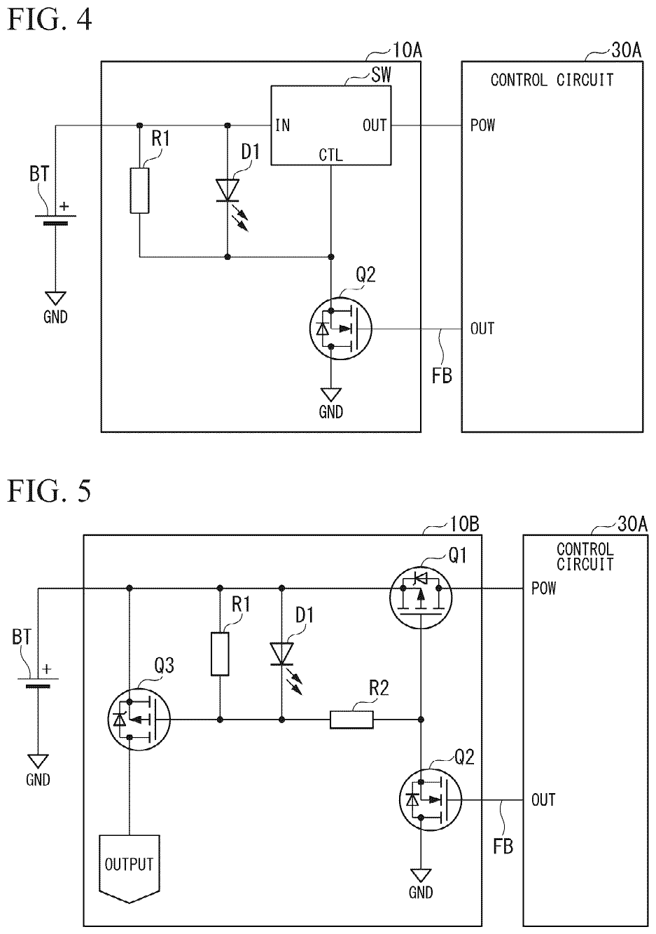

A second embodiment is a modified example of the first embodiment. FIG. 4 is a diagram illustrating a specific example of a configuration of an electronic device 1 according to the second embodiment. FIG. 4 illustrates a specific example of a circuit configuration of an electronic circuit 10A according to the second embodiment. In FIG. 4, elements corresponding to the constituents illustrated in FIG. 2 will be referred to by the same reference signs, and description thereof will be omitted.

The electronic circuit 10A illustrated in FIG. 4 is different from the electronic circuit 10 illustrated in FIG. 2, in that a switch integrated circuit (IC) SW is used instead of the P-channel MOSFET Q1 provided in the electronic circuit 10 illustrated in FIG. 2. Except for this point, the electronic circuit 10A illustrated in FIG. 4 is the same as the electronic circuit 10 illustrated in FIG. 2.

The switch IC SW includes an input terminal IN, an output terminal OUT, and a control input terminal CTL. The switch IC SW electrically connects the input terminal IN and the output terminal OUT (an electrically connected state) when the voltage applied to the control input terminal CTL is at the L level. On the other hand, the switch IC SW electrically disconnects the input terminal IN and the output terminal OUT (an electrically disconnected state) when the voltage applied to the control input terminal CTL is at the H level.

In the electronic circuit 10A illustrated in FIG. 4, similarly to the electronic circuit 10 illustrated in FIG. 2, when the external control signal FB is at the L level, the source and the drain of the N-channel MOSFET Q2 are electrically disconnected, and thus it is possible to switch the switch IC SW between in the electrically connected state and the electrically disconnected state of the input terminal IN and the output terminal OUT according to the whether the light emitting diode D1 is irradiated with light. Accordingly, when the external control signal FB is at the L level, it is possible to determine whether to supply electric power from the power supply BT to the control circuit 30A according to whether the light emitting diode D1 is irradiated with light. The control circuit 30A is configured such that the external control signal FB is at the L level when the control circuit 30A is in a non-started state.

When the external control signal FB is at the H level, the source and the drain of the N-channel MOSFET Q2 are electrically connected, and thus it is possible to fix the switch IC SW to the state in which the input terminal IN and the output terminal OUT are electrically connected regardless of whether the light emitting diode D1 is irradiated with light. Accordingly, when the external control signal FB is at the H level, it is possible to continue to supply electric power from the power supply BT to the control circuit 30A regardless of whether the light emitting diode D1 is irradiated with light.

In the second embodiment, similarly to the first embodiment, it is possible to achieve improvement of power supply on/off control using photovoltaic power which is generated from a photovoltaic element such as a light emitting diode in response to irradiation with light.

### Third Embodiment

FIG. 5 is a diagram illustrating a specific example of a configuration of an electronic device 1 according to a third embodiment. FIG. 5 illustrates a specific example of a circuit configuration of an electronic circuit 10B according to the third embodiment. In FIG. 5, elements corresponding to the constituents illustrated in FIG. 2 will be referred to by the same reference signs, and description thereof will be omitted.

The electronic circuit 10B illustrated in FIG. 5 is different from the electronic circuit 10 illustrated in FIG. 2, in that a P-channel MOSFET Q3 (a third switch) and a voltage division resistor R2 are added to the electronic circuit 10 illustrated in FIG. 2.

A source (a first terminal) of the P-channel MOSFET Q3 is connected to the plus terminal of the power supply BT, the anode of the light emitting diode D1, one terminal (the first terminal) of the pull-up resistor R1, and the source of the P-channel MOSFET Q1. Accordingly, the light emitting diode D1 is connected in a forward direction between the plus terminal of the power supply BT and the gate of the P-channel MOSFET Q1 and is connected in a forward direction between the plus terminal of the power supply BT and a gate of the P-channel MOSFET Q3.

When a negative voltage greater than a predetermined threshold voltage VTH3 with respect to the source voltage applied to the source is applied to the gate, the source and the drain of the P-channel MOSFET Q3 are electrically connected (an electrically connected state). On the other hand, when the negative voltage applied to the gate with respect to the source voltage applied to the source is not greater than the threshold voltage VTH3, the source and the drain of the P-channel MOSFET Q3 are electrically disconnected (an electrically disconnected state).

When the source and the drain of the P-channel MOSFET Q3 are electrically connected, the source voltage is output to the output terminal OUTPUT. On the other hand, when the source and the drain of the P-channel MOSFET Q3 are electrically disconnected, the source voltage is not output to the output terminal OUTPUT.

In the following description, becoming in the state in which the source and the drain of the P-channel MOSFET Q3 are electrically connected may be referred to as turning-on of the P-channel MOSFET Q3, being in the state in which the source and the drain of the P-channel MOSFET Q3 are in the electrically connected state may be referred to as being-on of the P-channel MOSFET Q3, becoming in the state in which the source and the drain of the P-channel MOSFET Q3 are electrically disconnected may be referred to as turning-off of the P-channel MOSFET Q3, and being in the state in which the source and the drain of the P-channel MOSFET Q3 are in the electrically disconnected state may be referred to as being-off of the P-channel MOSFET Q3.

The voltage applied to the source of the P-channel MOSFET Q3 may be referred to as a source voltage, or the voltage applied to the gate of the P-channel MOSFET Q3 may be referred to as a gate voltage.

The voltage division resistor R2 is connected in series to the pull-up resistor R1 between the cathode of the light emitting diode D1 and the gate of the P-channel MOSFET Q1.

In the electronic circuit 10B illustrated in FIG. 5, even when the N-channel MOSFET Q2 is turned on by the voltage division resistor R2, the P-channel MOSFET Q3 is not affected. This point will be described below.

In an initial state, the P-channel MOSFETs Q1 and Q3 in the electronic circuit 10B are turned off, and the N-channel MOSFET Q2 is turned off because the external control signal FB is at the L level. At this time, when the light emitting diode D1 is irradiated with light, the gate voltage of the P-channel MOSFET Q1 is decreased by photovoltaic power generated from the light emitting diode D1.

Here, a slight voltage drop is caused by the voltage division resistor R2 between the cathode of the light emitting diode D1 and the gate of the P-channel MOSFET Q1, but since the only current flowing in the voltage division resistor R2 is a leak current flowing in the gate of the P-channel MOSFET Q1 or between the source and the drain of the N-channel MOSFET Q2, the voltage drop is very small. Accordingly, when photovoltaic power sufficiently higher than the threshold voltage VTH1 of the P-channel MOSFET Q1 is generated by the light emitting diode D1, the P-channel MOSFET Q1 is turned on.

Accordingly, when the external control signal FB is at the L level, it is possible to switch ON/OFF of the P-channel MOSFET Q1 according to whether the light emitting diode D1 is irradiated with light. When the P-channel MOSFET Q1 is turned on, electric power is supplied from the power supply BT to the control circuit 30A. On the other hand, when the P-channel MOSFET Q1 is turned off, supply of electric power from the power supply BT to the control circuit 30A is not performed.

Then, when the external control signal FB is switched to the H level, the N-channel MOSFET Q2 is turned on, and thus a negative source voltage is applied to the gate of the P-channel MOSFET Q1. The negative source voltage is a negative voltage greater than the threshold voltage VTH1 with respect to the source voltage.

Accordingly, since the condition of the threshold voltage VTH1 is satisfied, the P-channel MOSFET Q1 continues to be turned on regardless of whether the light emitting diode D1 is irradiated with light when the external control signal FB is at the H level.

At this time, even when the external control signal FB is switched to the H level, the N-channel MOSFET Q2 is turned on, and thus the gate voltage of the P-channel MOSFET Q1 decreases, the gate voltage of the P-channel MOSFET Q3 is maintained substantially at the source voltage due to the voltage division resistor R2. The gate voltage of the P-channel MOSFET Q3 is determined by a ratio in resistance value (a voltage division ratio) between the pull-up resistor R1 and the voltage division resistor R2. In the relationship in resistance value (the voltage division ratio) between the pull-up resistor R1 and the voltage division resistor R2, when the N-channel MOSFET Q2 is turned on, a negative voltage greater than the threshold voltage VTH3 of the P-channel MOSFET Q3 with respect to the source voltage is not applied to the gate of the P-channel MOSFET Q3.

For example, when the resistance value of the pull-up resistor R1 is 1 MΩ and the resistance value of the voltage division resistor R2 is 10 MΩ, the gate voltage of the P-channel MOSFET Q3 is a voltage which is 10/11 of the source voltage (a voltage which is about 0.91 times the source voltage). In a specific example, since the threshold voltage VTH3 of the P-channel MOSFET Q3 is “0.9 V (max value)” and the source voltage of a silver oxide battery which is the power supply BT is “1.55 V.” the gate voltage “0.91×1.55=1.41” does not satisfy the condition of the threshold voltage VTH3 for turning on the P-channel MOSFET Q3. Accordingly, when the external control signal FB is at the H level, the P-channel MOSFET Q3 is turned off when the light emitting diode D1 is not irradiated with light and is turned on due to satisfaction of the condition of the threshold voltage VTH3 based on photovoltaic power of the light emitting diode D1 when the light emitting diode D1 is irradiated with light.

Accordingly, when the external control signal FB is at the H level, the P-channel MOSFET Q1 continues to be turned on regardless of whether the light emitting diode D1 is irradiated with light, and the P-channel MOSFET Q3 can be switched between ON and OFF according to whether the light emitting diode D1 is irradiated with light. When the P-channel MOSFET Q3 is turned on, the source voltage is output to the output terminal OUTPUT. On the other hand, when the P-channel MOSFET Q3 is turned off, the source voltage is not output to the output terminal OUTPUT.

In the aforementioned electronic circuit 10B illustrated in FIG. 5, when the external control signal FB is at the L level, a switch function of switching the P-channel MOSFET Q1 between ON and OFF according to the whether the light emitting diode D1 is irradiated with light is realized. Through this switch function, it is possible to switch ON/OFF of supply of electric power from the power supply BT to the control circuit 30A according to whether the light emitting diode D1 is irradiated with light.

On the other hand, when the external control signal FB is at the H level, the P-channel MOSFET Q1 is maintained in the ON state, and the switch function of switching the P-channel MOSFET Q3 between ON and OFF according to whether the light emitting diode D1 is irradiated with light is realized separately. Through this switch function, it is possible to switch the output to the output terminal OUTPUT according to whether the light emitting diode D1 is irradiated with light.

In the aforementioned electronic circuit 10B illustrated in FIG. 5, the switch function using the P-channel MOSFET Q1 and the switch function using the P-channel MOSFET Q3 can be realized by a single light emitting diode D1.

An example of usage of the output terminal OUTPUT will be described below.
Example 1 of usage of output terminal OUTPUT

By connecting the output terminal OUTPUT to the control circuit 30A such as a microcomputer, the control circuit 30A can detect whether the light emitting diode D1 is irradiated with light. Accordingly, it is possible to control whether the control circuit 30A is to perform a predetermined process according to whether the light emitting diode D1 is irradiated with light.
Example 2 of usage of output terminal OUTPUT

The electronic device 1 is applied to a wireless communication device. The wireless communication device can detect whether the light emitting diode D1 is irradiated with light using the output terminal OUTPUT. Accordingly, it is possible to control whether the wireless communication device is to perform a predetermined process according to whether the light emitting diode D1 is irradiated with light. For example, it is possible to control whether the wireless communication device is to emit radio waves according to whether the light emitting diode D1 is irradiated with light.
Example 3 of usage of output terminal OUTPUT

Pulse-like light (pulsed light) is used as light with which the light emitting diode D1 is irradiated. According to the electronic circuit 10B, even when light with which the light emitting diode D1 is irradiated is pulsed light, the output of the output terminal OUTPUT can be made to follow the pulsed light at a sufficient response speed. Accordingly, for example, by irradiating the light emitting diode D1 with pulsed light with modulated intensity, it is possible to realize an optical communication function of transmitting information such as a predetermined instruction or an identifier (ID) to a predetermined device via the output terminal OUTPUT. For example, by irradiating the light emitting diode D1 with pulsed light of which the intensity has been modulated using a specific modulation signal, the output terminal OUTPUT can be used to give a test instruction at the time of shipment of the electronic device 1.

An example of the usage of the output terminal OUTPUT has been described hitherto.

When the power supply BT is, for example, a silver oxide battery or a zinc air battery, it is preferable that the threshold voltage VTH1 of the P-channel MOSFET Q1, the threshold voltage VTH2 of the N-channel MOSFET Q2, and the threshold voltage VTH3 of the P-channel MOSFET Q3 range from 0.5 V to about 1.3 V.

In the specific example of the electronic circuit 10B illustrated in FIG. 5, the power supply BT is a silver oxide battery (with a source voltage of 1.55 V), the resistance value of the pull-up resistor R1 is 1 MΩ, the light emitting diode D1 is a red LED (a VF of 1.85 V), the threshold voltage VTH1 of the P-channel MOSFET Q1 is 0.9 V (max value), the threshold voltage VTH2 of the N-channel MOSFET Q2 is 0.9 V (max value), and the threshold voltage VTH3 of the P-channel MOSFET Q1 is 0.9 V (max value).

The threshold voltages VTH1, VTH2, and VTH3 may be different. For example, the threshold voltage VTH3 of the P-channel MOSFET Q3 may be lower than the threshold voltage VTH1 of the P-channel MOSFET Q1. When the threshold voltage VTH3 is lower than the threshold voltage VTH1, the voltage drop based on the voltage division resistor R2 can be cancelled, and thus the P-channel MOSFET Q3 can be turned on even when the light emitting diode D1 is irradiated with light of weak intensity.

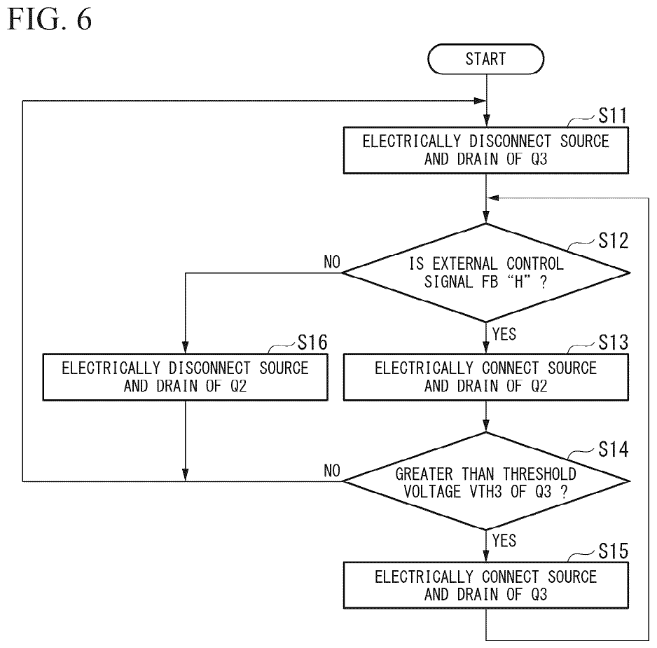

Operations of the electronic circuit 10B illustrated in FIG. 5 will be described below with reference to FIG. 6. FIG. 6 is a flowchart illustrating an operation example of the electronic circuit 10B according to the third embodiment.

In an initial state of the electronic circuit 10B, the P-channel MOSFETs Q1 and Q3 are turned off, and the N-channel MOSFET Q2 is turned off because the external control signal FB is at the L level. Accordingly, in the initial state, electric power is not supplied from the external control signal FB to the control circuit 30A. The output of the output terminal OUTPUT is at the L level when the P-channel MOSFET Q3 is turned off and is at the H level when the P-channel MOSFET Q3 is turned on.

The operation associated with the P-channel MOSFET Q3 will be mainly described below. The operations associated with the P-channel MOSFET Q1 and the N-channel MOSFET Q2 are the same as in those in the first embodiment illustrated in the flowchart of FIG. 3.

(Step S11) In the initial state, the P-channel MOSFET Q3 is turned off.

(Step S12) When the control circuit 30A starts and then outputs the external control signal FB at the H level (Step S12: YES), the process flow proceeds to Step S13. On the other hand, when the external control signal FB output from the control circuit 30A is at the L level (Step S12: NO), the process flow proceeds to Step S16.

(Step S13) Since the external control signal FB is at the H level, the N-channel MOSFET Q2 is turned on. Here, the N-channel MOSFET Q2 is turned on, but the gate voltage of the P-channel MOSFET Q3 is maintained almost at the source voltage and thus the P-channel MOSFET Q3 is turned off.

(Step S14) When the gate voltage of the P-channel MOSFET Q3 is a negative voltage greater than the threshold voltage VTH3 with respect to the source voltage through irradiation of the light emitting diode D1 with light (when the condition of the P-channel MOSFET Q3 is satisfied and the determination result of Step S14 is “YES”), the process flow proceeds to Step S15. On the other hand, when the condition of the threshold voltage VTH3 is not satisfied (when the determination result of Step S14 is “NO”), the process flow proceeds to Step S11.

(Step S15) Since the condition of the threshold voltage VTH3 is satisfied, the P-channel MOSFET Q3 is turned on. Accordingly, the output of the output terminal OUTPUT is changed from the L level to the H level. Thereafter, the process flow returns to Step S12.

(Step S16) Since the external control signal FB is at the L level, the N-channel MOSFET Q2 is turned off. Thereafter, the process flow returns to Step S11.

As described above, according to the third embodiment, it is possible to achieve improvement of power supply on/off control using photovoltaic power which is generated from a photovoltaic element such as a light emitting diode in response to irradiation with light. It is possible to realize control other than power supply on/off control using the P-channel MOSFET Q3 through the irradiation with light.

### Fourth Embodiment

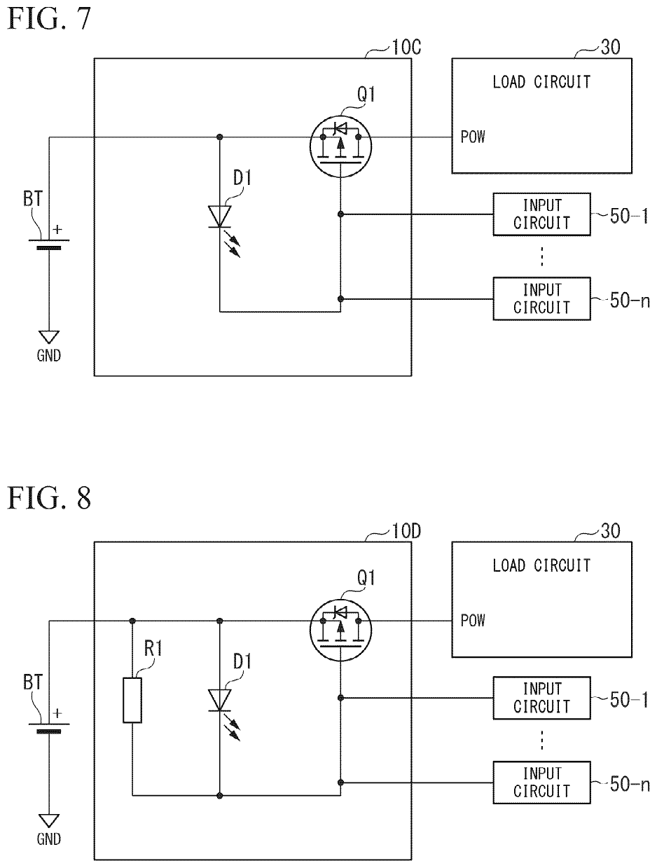

FIG. 7 is a diagram illustrating a specific example of a configuration of an electronic device 1 according to a fourth embodiment. FIG. 7 illustrates a specific example of a circuit configuration of an electronic circuit 10C according to the fourth embodiment. In FIG. 7, elements corresponding to the constituents illustrated in FIG. 2 will be referred to by the same reference signs, and description thereof will be omitted.

The electronic circuit 10C illustrated in FIG. 7 is different from the electronic circuit 10 illustrated in FIG. 2, in that the N-channel MOSFET Q2 and the pull-up resistor R1 are removed from the electronic circuit 10 illustrated in FIG. 2.

The gate of the P-channel MOSFET Q1 is supplied with output signals of n input circuits 50-1 to 50-n (where n is an integer equal to or greater than 1). These input circuits 50-1 to 50-n are formed in negative logic. The input circuits 50-1 to 50-n may have an arbitrary circuit configuration in which the output signal has the L level when electric power is supplied from the power supply BT to the load circuit 30. By supplying the output signals of the input circuits 50-1 to 50-n to the gate of the P-channel MOSFET Q1, the P-channel MOSFET Q1 can be controlled through a logical sum. That is, since the P-channel MOSFET Q1 is turned on when the gate of the P-channel MOSFET Q1 is switched to the L level, the P-channel MOSFET Q1 is turned on when any one output signal of the output signals of the input circuits 50-1 to 50-n becomes the L level.

With the electronic circuit 10C illustrated in FIG. 7, when all the output signals of the input circuits 50-1 to 50-n are at the H level, the P-channel MOSFET Q1 can be switched between ON and OFF according to whether the light emitting diode D1 is irradiated with light. On the other hand, when any one of the output signals of the input circuits 50-1 to 50-n is at the L level, the P-channel MOSFET Q1 can be turned on regardless of whether the light emitting diode D1 is irradiated with light. Accordingly, with the electronic circuit 10C illustrated in FIG. 7, whether electric power is supplied from the power supply BT to the load circuit 30 can be switched to whether the light emitting diode D1 is irradiated with light or can be switched to the output signals of the input circuits 50-1 to 50-n.

In an electronic circuit 10D illustrated in FIG. 8, the pull-up resistor R1 may be additionally provided in the electronic circuit 10C illustrated in FIG. 7. In the electronic circuit 10D illustrated in FIG. 8, similarly to the electronic circuit 10C illustrated in FIG. 7, whether electric power is supplied from the power supply BT to the load circuit 30 can be switched to whether the light emitting diode D1 is irradiated with light or can be switched to the output signals of the input circuits 50-1 to 50-n.

In FIGS. 7 and 8, the input circuits 50-1 to 50-n are provided, but the P-channel MOSFET Q1 may be switched between ON and OFF on the basis of only whether the light emitting diode D1 is irradiated with light without providing the input circuits 50-1 to 50-n. Accordingly, whether electric power is supplied from the power supply BT to the load circuit 30 can be switched according to only whether the light emitting diode D1 is irradiated with light.

The aforementioned embodiments can be applied in various types. For example, by applying the electronic device 1 to a device which is used in a liquid in a sealed state, it is possible to start the device in a non-contact manner by irradiation of the light emitting diode D1 with light. Examples of the device include a device that is used in water quality investigation and a small-sized camera device. Examples of the liquid include water, an electrolyte, and a body fluid.

While the present invention have been described above in conjunction with embodiments, the present invention is not limited to the embodiments, and various modifications and substitutions can be added thereto without departing from the gist of the present invention. The configurations in the aforementioned embodiments and examples may be combined.

1. An electronic circuit comprising:
a first switch including a first terminal connected to a power supply, a second terminal, and a control input terminal and electrically connecting the first terminal and the second terminal when a negative voltage greater than a predetermined threshold voltage with respect to a source voltage applied to the first terminal is applied to the control input terminal;
a photovoltaic element connected in a forward direction between the power supply and the control input terminal of the first switch and applying a negative voltage greater than the threshold voltage of the first switch with respect to the source voltage to the control input terminal of the first switch using photovoltaic power which is generated by irradiation with light;
a pull-up resistor that is connected in parallel to the photovoltaic element between the power supply and the control input terminal of the first switch; and
a second switch including a first terminal connected to the control input terminal of the first switch, a second terminal supplied with a negative voltage greater than the threshold voltage of the first switch with respect to the source voltage, and a control input terminal supplied with an external control signal input from the outside of the electronic circuit and electrically connecting the first terminal and the second terminal in response to the external control signal.

2. The electronic circuit according to claim 1, wherein the first switch is a P-channel MOSFET,
wherein the first terminal of the first switch is a source of the P-channel MOSFET,
wherein the second terminal of the first switch is a drain of the P-channel MOSFET, and
wherein the control input terminal of the first switch is a gate of the P-channel MOSFET.

3. (canceled)

4. (canceled)

5. The electronic circuit according to claim 1, wherein the second switch is an N-channel MOSFET,
wherein the first terminal of the second switch is a drain of the N-channel MOSFET,
wherein the second terminal of the second switch is a source of the N-channel MOSFET, and
wherein the control input terminal of the second switch is a gate of the N-channel MOSFET.

6. The electronic circuit according to claim 5, wherein the second terminal of the second switch is grounded or supplied with a negative source voltage of the power supply.

7. The electronic circuit according to claim 6, further comprising a third switch including a first terminal connected to the power supply, a second terminal, and a control input terminal and electrically connecting the first terminal and the second terminal when a negative voltage greater than a predetermined threshold voltage with respect to the source voltage applied to the first terminal is applied to the control input terminal,
wherein the photovoltaic element is further connected in a forward direction between the power supply and the control input terminal of the third switch.

8. The electronic circuit according to claim 7, further comprising a voltage division resistor connected in series to the pull-up resistor between a cathode of the photovoltaic element and the control input terminal of the first switch,
wherein a relationship in resistance value between the pull-up resistor and the voltage division resistor is set such that a negative voltage greater than the threshold voltage of the third switch with respect to the source voltage is not applied to the control input terminal of the third switch when the first terminal and the second terminal of the second switch are electrically connected.

9. The electronic circuit according to claim 8, wherein the third switch is a P-channel MOSFET,
wherein the first terminal of the third switch is a source of the P-channel MOSFET,
wherein the second terminal of the third switch is a drain of the P-channel MOSFET, and
wherein the control input terminal of the third switch is a gate of the P-channel MOSFET.

10. The electronic circuit according to claim 1, wherein the photovoltaic element is a red light emitting diode or an infrared light emitting diode.

11. (canceled)

12. An electronic device comprising:
the electronic circuit according to claim 1;
the power supply; and
a load circuit supplied with electric power of the power supply from the second terminal of the first switch.

13. An electronic device comprising:
the electronic circuit according to claim 1;
the power supply; and
a control circuit supplied with electric power of the power supply from the second terminal of the first switch,
wherein the control circuit outputs an external control signal supplied to the control input terminal of the second switch.

14. The electronic device according to claim 13, wherein the control circuit outputs the external control signal when a predetermined time has elapsed after the control circuit has started.

15. (canceled)
